(19) United States
(12) Patent Application Publication
(10) Pub. No.: US 2005/0174269 A1
(43) Pub. Date: Aug. 11, 2005

(54) Huffman decoder used for decoding both advanced audio coding (AAC) and MP3 audio

(75) Inventors: Bhaskar Sherigar, Bangalore (IN); RamanujanValmiki K., Bangalore (IN)

Correspondence Address: MCANDREWS HELD & MALLOY, LTD, 500 WEST MADISON STREET, SUITE 3400, CHICAGO, IL, 60661, US

(73) Assignee: Broadcom Corporation

(21) Appl. No.: 10/880,695

(22) Filed: Jun. 29, 2004

Related U.S. Application Data
(60) Provisional application No. 60/542,401, filed on Feb. 5, 2004.

(51) Int. Cl. H03M 7/40

(52) U.S. Cl. 341/65

(57) ABSTRACT

Aspects of the present invention may be found in a more efficient system and method of implementing Huffman decoding when audio is encoded or decoded using MPEG1 Layer 3 (MP3) or MPEG Advanced Audio Coding (AAC). Various aspects of the invention employ a unified architecture in the implementation of a Huffman decoder. Use of the unified architecture reduces the memory required to implement both MPEG1 Layer 3 (MP3) and MPEG Advanced Audio Coding (AAC) algorithms.

### RELATED APPLICATIONS/INCORPORATION BY REFERENCE

This application claims priority to provisional application for patent, Ser. No. 60/542,401, “HUFFMAN DECODER USED FOR DECODING BOTH ADVANCED AUDIO CODING (AAC) AND MP3 AUDIO”, filed Feb. 5, 2004, by Sherigar.

### FEDERALLY SPONSORED RESEARCH OR DEVELOPMENT

[Not Applicable].

[MICROFICHE/COPYRIGHT REFERENCE]

[Not Applicable].

### BACKGROUND OF THE INVENTION

MPEG audio standards have employed a number of compression technologies that have been introduced to reduce bandwidth required in a digital audio transmission. While minimizing the bandwidth required, these compression technologies have allowed the received digital audio to be reconstructed into audio of high perceptual speech quality.

When encoding the digital audio, the compression technologies used may employ Huffman coding. Encoding/decoding the digital audio is performed using a number of Huffman code tables, depending on the version or type of MPEG standard used. The Huffman code tables are used as a “codebook” to map audio data into corresponding Huffman coded data.

Huffman code tables requires significant memory space when both MPEG 1/2—Layer 3 as well as MPEG-2 AAC are implemented. The cost of manufacturing an integrated circuit increases with increases in memory space requirements. These additional costs may have a significant negative effect on a manufacturer's profit margin and its ability to competitively market its products.

Further limitations and disadvantages of conventional and traditional approaches will become apparent to one of skill in the art, through comparison of such systems with some aspects of the present invention as set forth in the remainder of the present application with reference to the drawings.

### BRIEF SUMMARY OF THE INVENTION

Aspects of the present invention may be found in a system and method to implement a unified architecture in the implementation of a Huffman decoder engine for AAC and MP3 audio algorithms.

In one embodiment, there is presented a Huffman decoder for decoding variable length coded data. The Huffman decoder comprises a memory for storing symbols. The memory comprises data words, wherein each of the data words stores a first symbol from a first variable length code data corresponding to a first audio compression standard, and a second symbol from a second variable length code corresponding to a second audio compression standard, or first variable length code data corresponding to the first audio compression standard.

In another embodiment, there is presented a Huffman decoder for decoding variable length data, comprising a first input, a second input, a memory, and an output. The first input receives input data. The second input receives a table identifier. The memory stores symbols and comprises data words. Each of the data words stores a first symbol from a first variable length code data corresponding to a first audio compression standard, and a second symbol from a second variable length code corresponding to a second audio compression standard, or first variable length code data corresponding to the first audio compression standard. The output provides one of the symbols based on the input data and the table identifier.

In another embodiment, there is presented a method for decoding variable length data. The method comprises receiving input data; receiving a table identifier; and providing a particular symbol based on the input data and the table identifier, from a memory storing a plurality of symbols, the memory comprising data words, wherein each of the data words stores a first symbol from a first variable length code data corresponding to a first audio compression standard, and a second symbol from a second variable length code corresponding to a second audio compression standard, or first variable length code data corresponding to the first audio compression standard.

These and other advantages, aspects, and novel features of the present invention, as well as details of illustrated embodiments, thereof, will be more fully understood from the following description and drawings.

### BRIEF DESCRIPTION OF THE DRAWINGS

FIG. 1 is a block diagram of an exemplary Huffman decoder in accordance with an embodiment of the present invention;

FIG. 2 is a more detailed diagram of a Huffman decoder in accordance with an embodiment of the present invention;

FIG. 3 is a block diagram describing a data word in accordance with an embodiment of the present invention;

FIG. 4 is a map of an exemplary Huffman ROM in accordance with an embodiment of the present invention;

FIG. 5 is a block diagram of an exemplary Huffman data path in accordance with an embodiment of the present invention; and

FIG. 6 is a timing diagram for decoding variable length coded data in accordance with an embodiment of the present invention.

### DETAILED DESCRIPTION OF THE INVENTION

Aspects of the present invention may be found in a more efficient system and method of implementing Huffman decoding when audio is encoded or decoded using MPEG1 Layer 3 (MP3) or MPEG Advanced Audio Coding (AAC). Various aspects of the invention employ a unified architecture in the implementation of a Huffman decoder. Use of the unified architecture reduces the memory required to implement both MPEG1 Layer 3 (MP3) and MPEG Advanced Audio Coding (AAC) algorithms.

Presented herein is a Huffman decoder used as a peripheral hardware module for Audio RISC (TARISC) that supports variable length coded (VLC) data decoding of advanced audio coding (AAC) and MPEG1 Layer 3 Audio (MP3) algorithms. It consumes data from an Extractor on issuing VLD instructions by the processor. The details of bits consumed and VLC decoded data, and the status regarding escape and error in the bit stream are passed to the processor. The Huffman decoder works on a table look up method by taking table ID as an input parameter. A Table ID input (5-bits) selects one of the many tables.

VLC decoded data is implemented by synthesized ROM of 20 bits wide which packs maximum of four results in single location of ROM. The sign associated with the VLC code is appended to the results at the end based on the type of the table, either signed or unsigned for AAC. In the case of MP3, the sign arrives in the stream itself and is processed in the Huffman block. In the case of AAC, the sign may be present or not depending on the property of the tables.

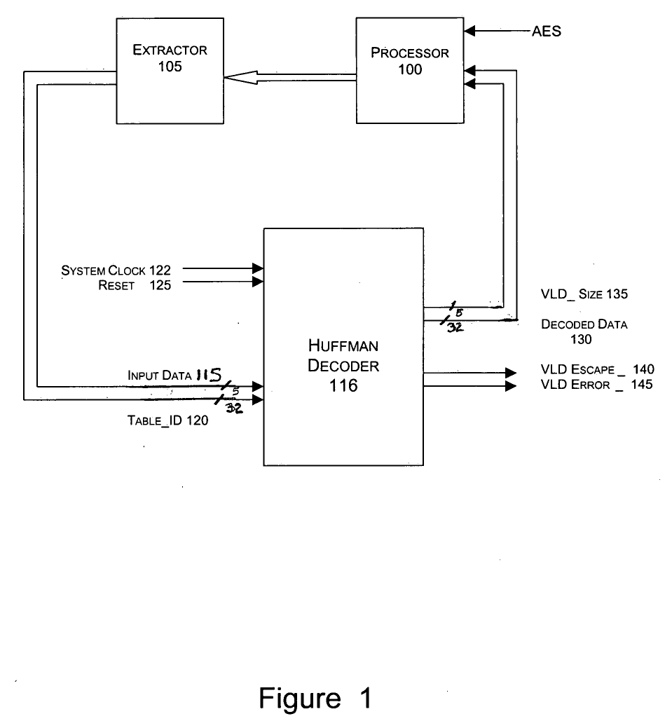

Referring now to FIG. 1, there is illustrated a block diagram of a Huffman decoder 116 in accordance with an embodiment of the present invention. The Huffman decoder 116 receives input data 115 and table identifiers 120 as inputs. The Huffman decoder 116 also receives a system clock 120 and has a reset port 125. The Huffman decoder 116 outputs decoded data 130, an indicator 135 indicating the number of bits of the input data 115 that are were consumed, a variable length decoding escape bit 140, and a variable length decoding error bit 145.

The Huffman decoder communicates with a processor 100 and an extractor 105. A processor 100 receives an audio elementary stream (AES) that is encoded in accordance with an audio compression standard such as, for example, MPEG 1, Layer 3 (MP3), or Advanced Audio Coding (AAC). The extractor 105 provides the input data 105 from the processor 100 to the Huffman decoder 116 as 32 bits in parallel. The extractor 105 also provides the table identifier 120 from the processor 100 to the Huffman decoder 116 as 5 bits in parallel.

The processor 100 controls the flow of data. The Huffman decoder 116 acts like a slave hardware module and provides decoded data 130 representing the Huffman decoded data for the input data 115. Because of the issue of VLD instruction, the decoded data 130 is clocked in the next clock period. The processor 100 reads and stores decoded data 130 in the second clock.

The AES is encoded in accordance with any one of several audio compression standards, such as MPEG 1, Layer 3 (MP3), or Advanced Audio Coding (AAC). The spectral data of the audio signal is coded with Huffman coding. Huffman coding is a reversible procedure for coding that, assigns shorter code-words to frequent symbols and longer code-words to less frequent signals (known as variable length coding VLC). Decoding of Huffman coded data is performed in look up table based decoding. There are 12 Huffman tables in AAC and 31 tables in MP3 algorithms respectively. Decoding of VLC data for AAC and MP3 are different. However, the Huffman decoder is capable of decoding both VLC data for both AAC and MP3.

Advanced Audio Coding

With respect to advanced audio coding (AAC), there are two bit stream elements; scale factor bands and spectral data are coded using Huffman code. All scale factors are transmitted using Huffman coded DPCM relative to the previous active scale factor. The first active scale factor is differentially coded relative to the “global gain”. This is Codebook number “0”, according to AAC specification and it is a simple look-up table based, unsigned and single dimension Huffman decode.

Huffman coded spectral data is recovered as the last part of the parsing of Individual Channel Stream (ICS). It consists all non-zero coefficients present in the “spectrum”. For each non-zero, non-intensity Codebook, the data are recovered via Huffman decoding in quads or pairs as indicated by the Codebooks. If the spectral data is associated with an unsigned Huffman Codebook, the sign bit(s) follow the Huffman code word. In case of the ESCAPE Codebook, if any escape value is received, a corresponding escape sequence will appear after that Huffman code. There may be zero, one or two escape sequences for each code word in the ESCAPE code book, as indicated by the presence of escape values in that decoded code word. For each section, the Huffman decoding continues until all the spectral values in that section have been decoded. The details of code books, dimension and sign are given in the Table #3 as follows.

TABLE 3
Scale Factor and Spectrum Huffman Code Book Parameters

| Code | | | Largest | Code Book | |
|---|---|---|---|---|---|
| Book | | | Absolute Value | listed in | Max |
| Number | Sign | Dimension | (LAV) | Table | Index |
| 0 | — | 1 | 0 | A.1 | 0-120 |
| 1 | 0 | 4 | 1 | A.2 | 0-80 |
| 2 | 0 | 4 | 1 | A.3 | 0-80 |
| 3 | 1 | 4 | 2 | A.4 | 0-80 |
| 4 | 1 | 4 | 2 | A.5 | 0-80 |
| 5 | 0 | 2 | 4 | A.6 | 0-80 |
| 6 | 0 | 2 | 4 | A.7 | 0-80 |
| 7 | 1 | 2 | 7 | A.8 | 0-63 |
| 8 | 1 | 2 | 7 | A.9 | 0-63 |
| 9 | 1 | 2 | 12 | A.10 | 0-168 |
| 10 | 1 | 2 | 12 | A.11 | 0-168 |
| 11 | 1 | 2 | 16 (Escape) | A.12 | 0-288 |
| 12 | — | — | Reserved | — | — |
| 13 | — | — | Reserved | — | — |
| 14 | — | — | Intensity out | — | — |
| | | | of phase | | |
| 15 | — | — | Intensity in- | — | — |
| | | | phase | | |

There is a single differential scale factor code book and eleven Huffman code books for spectral data. Four-tuples or two-tuples of quantized spectral coefficients are Huffman coded and transmitted starting from the lowest frequency coefficient and progressing to the highest frequency coefficient. Within a codeword that is associated with spectral four-tuples, the order of decoding is w,x,y,z. For code words associated with spectral two-tuples, the order of decoding is y,z. The result of Huffman decoding each differential scale factor code word is the code word index listed in the first column of code books A.1 through A.12. The spectrum Huffman code books encode four-tuples or two-tuples of signed or unsigned quantized spectral coefficients as was previously described in Table #3. Table #3 also indicates the largest absolute value (LAV) able to be encoded by each code book and defines a Boolean helper variable array, unsigned_cb[ ]. (i.e., 1 if code book is unsigned and 0 if signed).

The index from each table is translated to the n-tuple spectral values depending on the sign, dimension, and LAV. The following exemplary software program may be used.

if (unsigned[ ] ) {

Mod = lav + 1;
Off = 0;
}

else {

mod = 2* lav + 1;
off = lav;
}

if ( dim ==4 ) {

w = INT(idx/(mod*mod*mod))-off ;
idx-=(w+off)*(mod*mod*mod)
x = INT(idx/(mod*mod))-off ;
idx-=(x+off)*(mod*mod)
y = INT(idx/(mod))-off ;
idx-=(y+off)*(mod)
z = idx-off ;
}

else {

y = INT(idx/(mod))-off ;
idx-=(y+off)*(mod)
z = idx-off ;
}

If the Huffman code book represents signed values, the decoding of the quantized spectral n-tuple is complete after Huffman decoding and translation of code word index to quantized spectral coefficients. If the code book represents unsigned values, then the sign bits associated with non-zero coefficients immediately follow the Huffman code word, with a ‘1’ indicating a negative coefficient and a ‘0’ indicating a positive one.

The Escape code book is a special case. It represents values from 0 to 16 inclusive, but values from 0 to 15 encode actual data values, and the value 16 is an escape_flag that signals the presence of escape in y or z either of which will be denoted as an escape_sequence. This escape sequence permits quantized spectral values greater than 15 to be encoded. It consists of an escape_prefix of N 1's and followed by an escape_separator of one zero followed by an escape_word of N+4 bits that represents an unsigned integer value.

MPEG-1, Layer 3 (MP3)

With respect to MPEG-1 Layer 3 (MP3) Huffman coding, the spectral values of each granule are coded with different Huffman code tables. The full frequency range from zero to the Nyquist frequency is divided into several regions, which then are coded with different tables. Partition is done according to the maximum quantized values. Huffman coding of the spectral coefficients in case of MP3 is straightforward and does not require ‘unpacking’ used in AAC. There are total 33 Huffman table in which two tables have 4-tuple values and all other tables have 2-tuple values. The pairs of quantized values with an absolute value less than 15 are directly coded with Huffman code. If quantized values of magnitude greater than or equal to 15 are coded, the values are coded with a separate field following the Huffman code. If one or both values of a pair are not zeroing, one or two sign bits are appended to the code word.

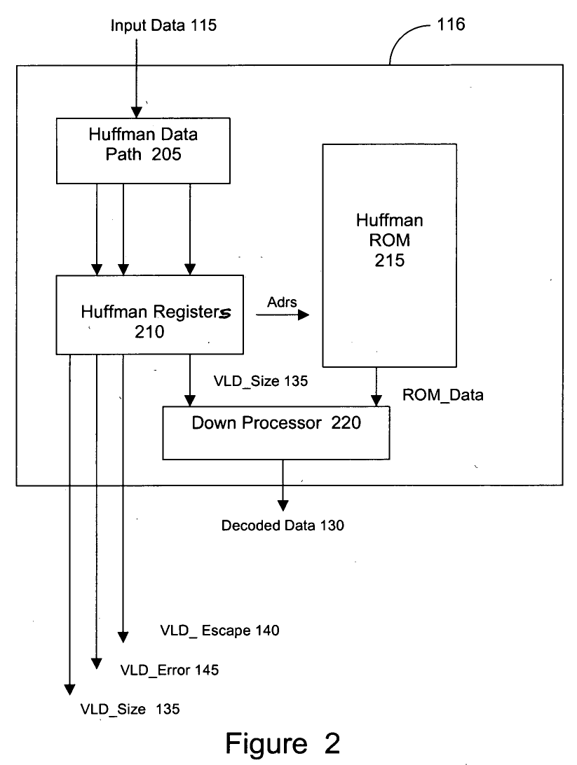

FIG. 2 is a detailed block diagram of a Huffman decoder 116 in accordance with an embodiment of the invention. The Huffman decoder 116 takes data from the extractor 105 and feeds decoded data 130 to the processor 100. Processor 100 uses the Huffman decoder 116 for execution of the variable length decoder (VLD) instruction.

VLD takes two clocks for the execution of the instruction. The processor 100 and the Huffman decoder 116 do not need handshake protocols to communicate with each other or the extractor 105. During the second clock of the VLD instruction execution valid decoded data 130 is available from the Huffman decoder 116. Huffman decoder 116 supplies 32 bit decoded data 130 along with the number of bits consumed 135.

Processor 100 takes care of supplying the bit stream-advance and number of bits consumed to the extractor 105. Presence of the Escape code 140 is also supplied with a separate wire to the processor flag, in the case when error in the bit stream or error in the decode Processor is informed with VLD_Error flag 145. Decoding of AAC or MP3 algorithm is transparent to the Huffman decoder 116. Table Select 120 at the time of VLD instruction execution determines the algorithm according to which the decoding is performed.

The Huffman decoder 116 may consume up to 23 bits for AAC and MP3, including 4 bits of sign for the case of 4-tuple VLC input code. In case of 2-tuple VLC decoded data, the sign bits are two bits for 2-tuples.

The Huffman decoder 116 includes a Huffman Data Path 205, Huffman Registers 210, a Huffman ROM 215, and a down processor 220. The Huffman Registers 210 receive the input data stream from the extractor 105. The Huffman registers 210 indicate the number of bits consumed, VLD_Size, the presence of an error, VLD_Error, or an escape code, VLD_Escape, and generates an address, Adrs, from the Huffman ROM 215. The Huffman ROM 215 provides data, ROM_data, from the address, adrs, provided by the Huffman registers 210 to the down processor 220. The down processor 220 concatenates the data, depending on the algorithm and type of the output indicated by the VLD_Size.

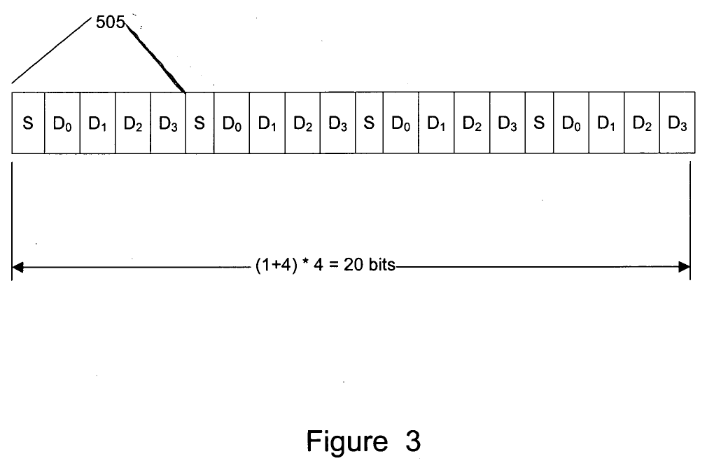

Referring now to FIG. 3, there is illustrated a block diagram of the data structure of the packed decoded data in accordance with an embodiment of the invention. As illustrated, the total width of the Huffman ROM 215 is 20 bits, which accommodates 4-tuple values 505 that are 5 bits wide, SD₀D₁D₂D₃. Each tuple has a sign bit at MSB (e.g., 5th bit), S, while the remaining four bits D₀D₁D₂D₃ comprises magnitude. 4-tuples w,x,y,z (in the case of AAC) and v,w,x,y (in the case of MP3) pack the entire width, but 2-tuples occupy either lower half, D₂D₃, of the 4-tuple values or are implemented using separate 2-tuple values. The decoded values are identical in both AAC and MP3 in most of the cases and the ROM depth is compressed to 492 locations.

Table 4 is an exemplary scheme for packing Huffman tables for AAC and MP3. The MP3 algorithm bit stream allows sign bits to follow the VLCs, but AAC restricts the sign bits to few of the code books, while the remaining sign bits are built within the code books itself (e.g., see Table #3). The VLC tables for which signs arrive in the stream are processed and appended to the decoded data (VLD_Data) and for those that come with no signs are directly passed to the processor. For Escape coded VLCs, only an indication of the presence of Escape is passed and is not decoded in the Huffman decoder for both AAC and MP3 by way of the VLD_Escape Signal. The Escape code may be present in either of the 2-tuples (y or z) or both. A fixed value of 15 (MP3) or 16 (AAC) is sent as Escape code to the processor in the VLD_Data. The sign of the Escape code is not processed in the Huffman block. In addition to the Huffman table mentioned in AAC and MP3, there is a hidden Escape Huffman table in AAC. In the case of MP3, some of the table repeats itself for different number of Escape coded bits, such table share common VLCs (Table 16 to 23 and table 24 to 31). Table 0, Table 4, table 14 are not used in MP3.

TABLE 4

| | | Hardware |
|---|---|---|
| | Huffman Table Ids (As in | Huffman |
| Sl. No | Specification) | Table ID |
| 1 | AAC-Table A.1 | 00 |
| 2 | AAC-Table A.2 (Code book 1) | 01 |
| 3 | AAC-Table A.3 (Code book 2) | 02 |
| 4 | AAC-Table A.4 (Code book 3) | 03 |
| 5 | AAC-Table A.5 (Code book 4) | 04 |
| 6 | AAC-Table A.6 (Code book 5) | 05 |
| 7 | AAC-Table A.7 (Code book 6) | 06 |
| 8 | AAC-Table A.8 (Code book 7) | 07 |
| 9 | AAC-Table A.9 (Code book 8) | 08 |
| 10 | AAC-Table A.10 (Code book 9) | 09 |
| 11 | AAC-Table A.11 (Code book 10) | 10 |
| 12 | AAC-Table A.12 (Code book 11) | 11 |
| 13 | AAC-Table (Hidden Escape Table) | 12 |
| 14 | MP3-Table A (Quadruple Table) | 13 |
| 15 | MP3-Table B (Quadruple Table) | 14 |
| 16 | MP3-Table 1 | 15 |
| 17 | MP3-Table 2 | 16 |
| 18 | MP3-Table 3 | 17 |
| 19 | MP3-Table 5 | 18 |
| 20 | MP3-Table 6 | 19 |
| 21 | MP3-Table 7 | 20 |
| 22 | MP3-Table 8 | 21 |
| 23 | MP3-Table 9 | 22 |
| 24 | MP3-Table 10 | 23 |
| 25 | MP3-Table 11 | 24 |
| 26 | MP3-Table 12 | 25 |
| 27 | MP3-Table 13 | 26 |
| 28 | MP3-Table 15 | 27 |
| 29 | MP3-Table 16 to 23 | 28 |
| 30 | MP3-Table 24 to 31 | 29 |

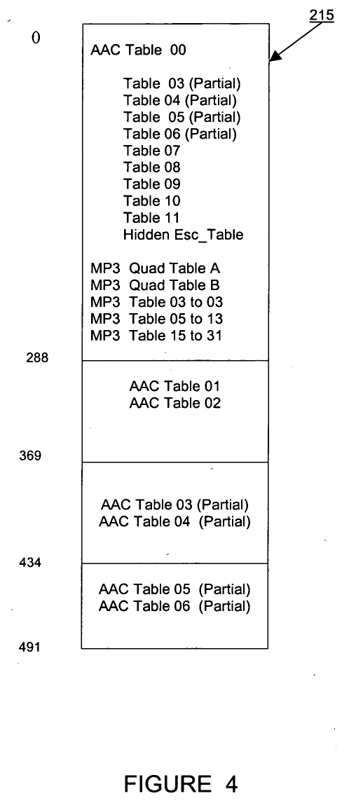

FIG. 4 is an exemplary map of a Huffman ROM 215 in accordance with an embodiment of the invention. Decoded values for the input VLCs are stored in ROM (combinational logic) and appropriate address is pointed to give out the “Packed” Values. The index values for AAC range from 0 to 288 (Code book 11 is largest). All other unsigned tables will have decoded values in this range, but for signed tables (code book 0, 1, 3 and 4), the ROM values are different. 4-tuple VLC codes have different ROM values and can be signed or unsigned. All MP3 Huffman tables except quadruple table A and quadruple table B have the ROM values which come under AAC VLCS. Common ROM contents are addressed because two algorithms are not supported simultaneously.

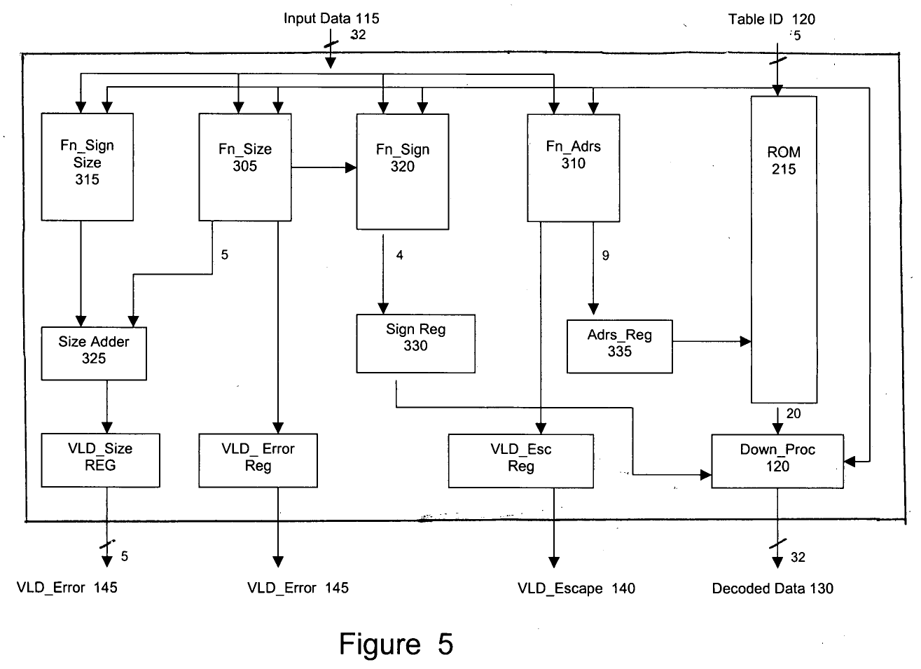

Referring now to FIG. 5 is a block diagram illustrating the data path flow of the Huffman decoder in accordance with an embodiment of the invention. Separate functions indicate the number of bits consumed (Fn_Size 305), the address to be generated (Fn_Adrs 310), and number of sign bits present (Fn_Sign Size 315). The Huffman decoder 116 also include a function indicating the sign (Fn_Sign 320). Each of the foregoing functions receive the input data 115 and a Table Identifier 120 from the extractor 105.

A size adder 325 adds the outputs from the functions Fn_Sign Size 315 and Fn_Size 305 to provide VLD_Size 135, indicating the number of bits that are consumed. The function Fn_Size 305 controls the error flag, VLD_Error 145, while the function Fn_Adrs 310 controls the escape flag, VLD_Escape 140. A sign register 330 provides the 4 sign bits from the function Fn_Sign 320 to the down processor 120. An address register 335 provides the address generated by function, Fn_Adrs 310 to the Huffman ROM 215. The Huffman ROM 215 provides 20 bits of packed data to the down processor 120. The down processor 120 concatenates the sign bits from the sign register 330 and the bits from the Huffman ROM 215 based on the table identifier 120 provided by the extractor 105.

FIG. 6 is a diagram describing the timing flow within the Huffman decoder 116 when a VLD Instruction is issued, in accordance with an embodiment of the invention. VLD instruction execution uses two clocks and the result of decode will be available at the output of the Huffman decoder during the second clock (i.e, at second decode cycle of the Processor).

At clock cycles 0 and 1 (System Clock 120), the processor 100 receives VLD instructions, VLD1, and VLD2, respectively. At clock cycles 1 and 2, the processor 100 decodes instructions VLD1 and VLD2 (Decode Cycle), respectively. At clock cycles 2 and 3, the processor 100 executes the instructions VLD1 and VLD2 (Execute Cycle), respectively. At clock cycles 2 and 3, the extractor 105 provides input data, Data 0, and a table identifier, ID1, corresponding to instruction VLD1 to the Huffman Decoder 116. During cycles 3 and 4, the Huffman decoder 116 provides the decoded data, VLD_data 0, and VLD_Size, Size 1. At clock cycles 4 and 5, the extractor 105 provides input data, Data 1, and a table identifier, ID2, corresponding to instruction VLD2 to the Huffman Decoder 116. During cycles 5 and 6, the Huffman decoder 116 provides the decoded data, VLD_data 1, and VLD_Size, Size 2.

In one embodiment, actual ROMs instead of combinatorial logic can be used. Replacing with actual ROM is very simple. Address registers may be eliminated when synchronous ROMs are used.

The table Id details serve as firmware guidelines to chose correct VLD instruction parameters. The following assembly code segment shows the usage of VLD instruction:

| | | | | |
|---|---|---|---|---|
| | MOVI | R3, #29 | ; | Table Sel = 29 |
| | VLD | R0, R3 | ; | Perform VLD for Table |
| | | | ; | 29 and store the |
| | | | ; | result in R0 |
| | BLE | Error_handle | ; | Do Error Handling |
| | BLT | Escape_handle | ; | Escape Handling |
| | NOV | R2, R0 | ; | Save Result |
| | VLD | R0, R3 | ; | Continue VLD |
| Error_handle | STRI | R0, Error_status | ; | Store Error status |
| | | | ; | Do Error Handling |
| | RET | | ; | Return |
| Escape_handle | EXT | R0, R4 | ; | Extract Escape data |
| | | | ; | Do Escape decode |
| | RET | | ; | Return |

While the invention has been described with reference to certain embodiments, it will be understood by those skilled in the art that various changes may be made and equivalents may be substituted without departing from the scope of the invention. In addition, many modifications may be made to adapt a particular situation or material to the teachings of the invention without departing from its scope. Therefore, it is intended that the invention not be limited to the particular embodiment disclosed, but that the invention will include all embodiments falling within the scope of the appended claims.

1. A Huffman decoder for decoding variable length coded data, said Huffman decoder comprising:
a memory for storing symbols, said memory comprising data words, wherein each of the data words stores a first symbol from a first variable length code data corresponding to a first audio compression standard, and a second symbol from a second variable length code data corresponding to a second audio compression standard or first variable length code data corresponding to the first audio compression standard.

2. The Huffman decoder of claim 1, wherein the data words comprise a plurality of bits, the plurality of bits storing the first symbol, and wherein a portion of the plurality of bits store the second symbol.

3. The Huffman decoder of claim 1, wherein the first audio compression standard comprises advanced audio compression and wherein the second audio compression standard comprises MPEG-1, Layer 3.

4. A Huffman decoder for decoding variable length data, said Huffman decoder comprising:
a first input for receiving input data;
a second input for receiving a table identifier;
a memory for storing symbols, said memory comprising data words, wherein each of the data words stores a first symbol from a first variable length code corresponding to a first audio compression standard, and a second symbol from a second variable length code corresponding to a second audio compression standard; and
an output for providing one of the symbols based on the input data and the table identifier.

5. The Huffman decoder of claim 4, wherein the data words comprise a plurality of bits, the plurality of bits storing the first symbol data, and wherein a portion of the plurality of bits stores the second symbol or first variable length code data corresponding to the first audio compression standard.

6. The Huffman decoder of claim 4, wherein the first audio compression standard comprises advanced audio compression and wherein the second audio compression standard comprises MPEG-1, Layer 3.

7. The Huffman decoder of claim 4, further comprising another output indicating the number of bits of the input data that are represented by the one of the symbols.

8. A method for decoding variable length data, said method comprising:
receiving input data;
receiving a table identifier; and
providing a particular symbol based on the input data and the table identifier, from a memory storing a plurality of symbols, the memory comprising data words, wherein each of the data words stores a first symbol from a first variable length code corresponding to a first audio compression standard, and a second symbol from a second variable length code corresponding to a second audio compression standard.

9. The method of claim 8, wherein the data words comprise a plurality of bits, the plurality of bits storing the first symbol, and wherein a portion of the plurality of bits store the second symbol or first variable length code data corresponding to the first audio compression standard.

10. The method of claim 8, wherein the first audio compression standard comprises advanced audio compression and wherein the second audio compression standard comprises MPEG-1, Layer 3.

11. The method of claim 8, further comprising:
indicating the number of bits of the input data that are represented by the particular symbol.
